(19) United States
(12) Patent Application Publication
(10) Pub. No.: US 2025/0293194 A1
(43) Pub. Date: Sep. 18, 2025

(54) Molded Electronic Component Having a Metallic Loops Embedded in a Mold Compound

(71) Applicant: Infineon Technologies Austria AG, Villach (AT)

(72) Inventors: Andreas Grassmann, Sinzing (DE); Ivan Nikitin, Regensburg (DE)

(21) Appl. No.: 18/605,078

(22) Filed: Mar. 14, 2024

(51) Int. Cl. H01L 23/00; H01L 21/48; H01L 23/31; H01L 25/00; H01L 25/065

(52) U.S. Cl. CPC H01L 24/45; H01L 21/4853; H01L 23/3121; H01L 24/08; H01L 24/48; H01L 25/0655; H01L 25/50; H01L 2224/08245; H01L 2224/45014; H01L 2224/45015; H01L 2224/48175; H01L 2924/181

(57) ABSTRACT

A molded electronic component includes a mold compound, a die assembly, a plurality of metallic loops, and a metallic body. The die assembly includes a semiconductor die attached to a substrate. The die assembly is at least partly embedded in the mold compound. The plurality of metallic loops is embedded in the mold compound and attached to the die assembly. The metallic body is partly embedded in the mold compound and has a first surface that is exposed from the mold compound. The metallic body is attached to each of the plurality of metallic loops at a second surface of the metallic body opposite the first surface.

### BACKGROUND

Molded electronic components offer a number of advantages such as the ability to incorporate complex chip layouts, e.g., system in package (SiP) designs, and provide these as single components that can be built into modules, systems, and other assemblies. Molded electronic components include one or more semiconductor dies that are provided on one or more substrates, such as a lead frame, and are embedded in a mold compound. External component terminals may be provided on one or more surfaces of the mold compound by metallic bodies, such as copper or aluminum clips, that are electrically coupled to terminals of the semiconductor die(s) and/or the substrate(s) through bond wires, metallic ribbons, or other means. As the layout complexity of these molded electronic components increases and their size decreases, proper alignment of the component terminals may become increasingly critical to ensuring that a molded electronic component can be reliably integrated into the module, system, assembly, etc., and may be associated with tighter alignment tolerances that increase manufacturing complexity and/or cost.

Thus, there is a need for a solution that increases alignment tolerance of component terminals in manufacturing molded electronic components.

### SUMMARY

According to an embodiment of a molded electronic component, the molded electronic component comprises: a mold compound; a die assembly comprising a semiconductor die attached to a substrate, the die assembly at least partly embedded in the mold compound; a plurality of metallic loops embedded in the mold compound and attached to the die assembly; and a metallic body partly embedded in the mold compound and having a first surface that is exposed from the mold compound, wherein the metallic body is attached to each of the plurality of metallic loops at a second surface of the metallic body opposite the first surface.

According to an embodiment of a power electronics assembly, the power electronics assembly comprises: a printed circuit board; a molded electronic component embedded in the printed circuit board and comprising: a mold compound; a die assembly comprising a semiconductor die attached to a substrate, the die assembly at least partly embedded in the mold compound; a plurality of metallic loops embedded in the mold compound and attached to the die assembly; and a metallic body partly embedded in the mold compound and having a first surface that is exposed from the mold compound, wherein the metallic body is attached to each of the plurality of metallic loops at a second surface of the metallic body opposite the first surface; and an electronic device electrically connected to the molded electronic component through the printed circuit board.

According to method of producing a molded electronic component, the method of producing the molded electronic component comprises: attaching a semiconductor die to a substrate to form a die assembly; attaching a plurality of metallic loops to the die assembly; attaching a first surface of a metallic body to each of the plurality of metallic loops; enclosing the die assembly, the plurality of metallic loops, and the metallic body in a mold such that the mold presses the metallic body and the die assembly towards one another and compresses the plurality of metallic loops; and injecting a liquified mold compound into the mold.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a perspective view of a molded electronic component, according to an embodiment.

FIG. 1B illustrates a perspective view of a molded electronic component, according to an embodiment.

FIG. 2 illustrates a side cross-sectional view of a molded electronic component, according to an embodiment.

FIG. 3 illustrates a side cross-sectional view of a molded electronic component, according to an embodiment.

FIG. 4 illustrates a side cross-sectional view of a molded electronic component, according to an embodiment.

FIG. 5 illustrates a side cross-sectional view of a molded electronic component, according to an embodiment.

FIG. 6 illustrates a side cross-sectional view of a molded electronic component, according to an embodiment.

FIG. 7 illustrates a side cross-sectional view of a molded electronic component, according to an embodiment.

FIG. 8 illustrates a side cross-sectional view of a molded electronic component, according to an embodiment.

FIGS. 9A through 9G illustrate a method of producing a molded electronic component, according to an embodiment.

### DETAILED DESCRIPTION

Described herein is a molded electronic component, for example a molded power semiconductor component, having higher tolerance to misalignment of component terminals during manufacturing when compared to other similar molded electronic components. The higher tolerance is achieved by attaching and electrically coupling the component terminals, e.g., provided by metallic bodies such as clips, to a die assembly of the molded electronic component using metallic loops. The metallic loops may be formed from wires such as bond wires, metallic ribbon, fibers, or another elongated conductive body. The metallic loops may be attached to semiconductor dies of the die assembly, pads or traces on a substrate of the die assembly (e.g., a lead frame), leads, and/or other features of the die assembly of the molded electronic component.

Attaching the component terminals to a die assembly of a molded electronic component using metallic loops may, in some examples, increase the vertical alignment tolerance of the component terminals during manufacturing of the molded electronic component. Specifically, the metallic loops are flexible, and a vertical force, such as one applied to the component terminals by one or more surfaces of a molding tool prior to dispensing a liquified mold compound to form the mold compound of the molded electronic component, may compress the metallic loops in a manner that causes the component terminals to parallelly align against the surface(s) of the molding tool and with one another, and may eliminate any gaps between the component terminals and the surface(s) of the molding tool. The liquified mold compound may then be dispensed to form the mold compound while the component terminals are aligned under the force of the surface(s) of the molding tool, resulting in surfaces of the component terminals being flush with a surface of the mold compound. That is, any vertical misalignment of the component terminals that is present prior to forming the mold compound may be reduced or eliminated during the formation of the mold compound, potentially enabling component designs with higher complexity and/or finer critical dimensions without significantly increasing manufacturing complexity and/or cost.

Described next, with reference to the figures, are exemplary embodiments of the molded electronic component and a method of producing the molded electronic component.

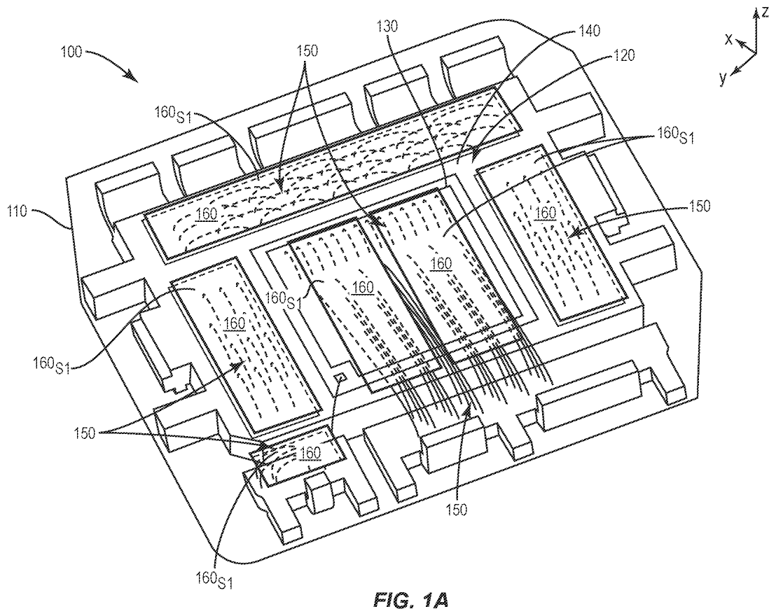

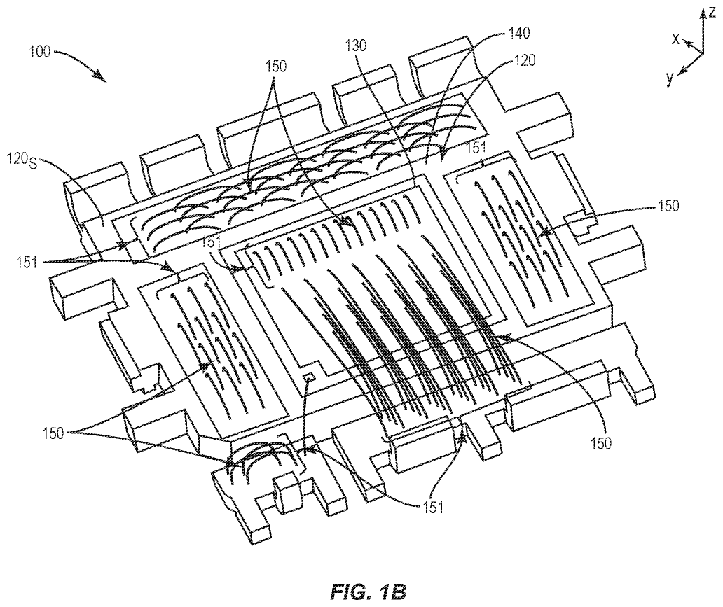

FIG. 1A illustrates a perspective view of a molded electronic component 100, according to an embodiment.

The molded electronic component 100 includes a die assembly 120 at least partly embedded in a mold compound 110. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc. Only an outline of the mold compound 110 is shown in FIG. 1A so that the parts embedded in the mold compound 110 are visible.

The die assembly 120 includes one or more semiconductor dies (chips) 130 attached to a substrate 140. The semiconductor die 130 may include one or more devices, including transistors, diodes, resistors, capacitors, and/or other types of active or passive devices. In one embodiment, the semiconductor die 130 is a vertical power transistor die. For a vertical power transistor die, the primary current flow path is between the front and back sides of the die 130 (along the z direction in FIG. 1A). For example, a drain pad may be disposed at the die backside, with gate and source pads (and optionally one or more sense pads) at the die frontside. The semiconductor die 130 instead may be a lateral power transistor die. For a lateral power transistor die, the primary current flow path is along the front side of the die 130 (along the x or y direction in FIG. 1A).

In one embodiment, the semiconductor die 130 is a SiC power MOSFET (metal-oxide-semiconductor field-effect transistor) die. The semiconductor die 130 instead may be Si power MOSFET die, HEMT (high-electron mobility transistor) die, IGBT (insulated-gate bipolar transistor) die, JFET (junction filed-effect transistor) die, etc.

The semiconductor die(s) 130 and/or their constituent devices may be arranged to form all or part of a power electronics circuit such as a DC/AC inverter, a DC/DC converter, an AC/DC converter, a DC/AC converter, an AC/AC converter, a multi-phase inverter, an H-bridge, motor driver, etc. In some examples, a power electronics circuit that includes the semiconductor die(s) 130 is a half-bridge or full-bridge circuit. The substrate 140 may be a printed circuit board (PCB), lead frame, or other substrate, e.g., insulated metal substrate (IMS), a DCB (direct copper bonded) substrate, an AMB (active metal brazed), etc.

According to an embodiment, the molded electronic component 100 includes a plurality of metallic loops 150 embedded in the mold compound 110 and attached to the die assembly 120. The plurality of metallic loops 150 may be attached to the semiconductor die 130, e.g., a contact pad of the semiconductor die 130, the substrate 140, e.g., a contact pad, trace, etc. of the substrate 140, and/or another feature of the molded electronic component 100 (e.g., a lead terminal). The plurality of metallic loops 150 may be formed from wires such as bond wires, metallic ribbon, fibers, and/or another elongated conductive body. The wires, metallic ribbon, fibers, and/or another elongated conductive body may include copper, aluminum, another metal or metal alloy, and/or another suitable conductive material.

The molded electronic component 100 includes metallic bodies 160 (e.g., copper or aluminum clips) that are partly embedded in the mold compound 110. Each of the metallic bodies 160 has a first surface 160_{S1} that is exposed from the mold compound 110. The metallic bodies 160 are attached to each of the plurality of metallic loops 150 at a second surface of a respective metallic body 160 that is opposite the first surface 160_{S1} of the respective metallic body 160. The metallic bodies 160 may be attached to each of the plurality of metallic loops 150 by laser-welded joints, adhesive, glue, solder joints, and/or other attachment means. The plurality of metallic loops 150 electrically couples each of the metallic bodies 160 to a feature of the die assembly 120 (e.g., the semiconductor die 130, a trace of the substrate 140 that is electrically coupled to the semiconductor die 130), with one or more of the metallic bodies 160 forming a component terminal of the molded electronic component 100 (e.g., source terminal, emitter terminal, drain terminal, collector terminal, gate terminal, anode terminal, cathode terminal, etc.).

Attaching the metallic bodies 160 to the die assembly 120 using the plurality of metallic loops 150 as described herein may, in some examples, increase the vertical alignment tolerance of the metallic bodies 160 during manufacturing of the molded electronic component 100. Specifically, the plurality of metallic loops 150 are flexible, and a vertical force, such as one applied to the metallic bodies 160 by one or more surfaces of a molding tool prior to dispensing a liquified mold compound to form the mold compound 110, may compress the plurality of metallic loops 150 in a manner that causes the metallic bodies 160 to parallelly align against the surface(s) of the molding tool and with one another and may eliminate any gaps between the metallic bodies 160 and the surface(s) of the molding tool. The metallic loops 150 may also be not merely flexible, but also resilient such that they act as a spring against a vertical force, for example that applied by a molding tool. This may ensure that the metallic loops 150 remain in contact with the metallic bodies 160 throughout the forming of the mold compound 110. The liquified mold compound may then be dispensed to form the mold compound 110 while the metallic bodies 160 are aligned under the force of the surface(s) of the molding tool, resulting in the first surfaces 106_{S1} of the metallic bodies 160 of the molded electronic component 100 being flush with a surface of the mold compound 110. That is, any vertical misalignment of the metallic bodies 160 that is present prior to forming the mold compound 110 may be reduced or eliminated during the formation of the mold compound 110, potentially enabling component designs with higher complexity and/or finer critical dimensions.

FIG. 1B illustrates a perspective view of the molded electronic component 100 of FIG. 1A, with the mold compound 110 and the metallic bodies 160 omitted to illustrate the arrangement of the plurality of metallic loops 150. In the example of FIG. 1B, the plurality of metallic loops 150 is arranged in a plurality of rows 151 of metallic loops 150 on a surface 120_{S} of the die assembly 120. Some of the plurality of metallic loops 150 are arranged on the semiconductor die 130, while other of the plurality of metallic loops 150 are arranged on the substrate 140. Other arrangements of the plurality of metallic loops 150 are contemplated (e.g., clusters, radial arrangements, linear arrangements, arrangements in which all of the plurality of metallic loops 150 are arranged on the semiconductor die 130 or the substrate 140, etc.).

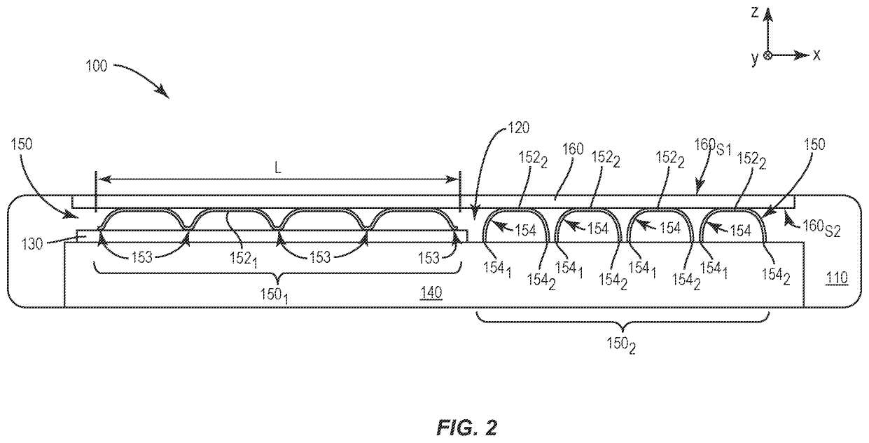

FIG. 2 illustrates a side cross-sectional view of the molded electronic component 100, according to an embodiment. FIG. 2 illustrates one example of the molded electronic component 100 of FIG. 1 and may include features of the other examples described herein.

The plurality of metallic loops 150 of the molded electronic component 100 of FIG. 2 includes a first plurality 150₁ of metallic loops 150 and a second plurality 150₂ of metallic loops 150 each embedded in the mold compound 110 and attached to the die assembly 120. In this example, the first plurality 150₁ of metallic loops 150 is attached to the semiconductor die 130 and the second plurality 150₂ of metallic loops 150 is attached to the substrate 140. Other arrangements, e.g., arrangements in which both the first plurality 150₁ and the second plurality 150₂ of metallic loops 150 are both attached to the semiconductor die 130 and/or the substrate 140, are contemplated.

The first plurality 150₁ of metallic loops 150 is shaped from an elongated conductive body 152₁ that is attached to the die assembly 120 at plurality of positions 153 along a length L of the elongated conductive body 152₁. The second plurality 150₂ metallic loops 150 is shaped from discrete segments 154 of an elongated conductive body 152₂. Each segment 154 of the elongated conductive body 152₂ includes a first end 154₁ and a second end 154₂ that are attached e.g., by a wire bond or solder, to the die assembly 120 at plurality of positions. In this example, the segments 154 are attached to the substrate 140. In other examples, one or both of the first end 154₁ and the second end 154₂ of one or more of the segments 154 may be attached to the semiconductor die 130. Each of the elongated conductive bodies 152₁ and 152₂ may be a wire such a bond wire, a metallic ribbon, a fiber, or another elongated conductive body.

In this example, the metallic body 160 is attached to each of the first plurality 150₁ and the second plurality 150₂ of metallic loops 150 at a second surface 160_{S2} of the metallic body 160 opposite the first surface 160_{S1}. The metallic body 160 may be attached to each of the first plurality 150₁ and the second plurality 150₂ of metallic loops 150 by a laser-welded joint, an adhesive, a glue, a solder joint, and/or another attachment means.

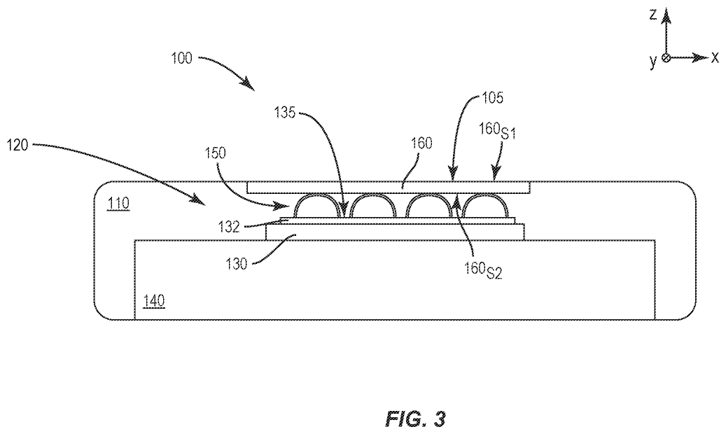

FIG. 3 illustrates a side cross-sectional view of the molded electronic component 100, according to an embodiment. FIG. 3 illustrates one example of the molded electronic component 100 of FIG. 1 and may include features of the other examples described herein.

In the example of molded electronic component 100 of FIG. 3, each of the plurality of metallic loops 150 is attached to the die assembly 120 at a position on a contact pad 132 (e.g., a metallic pad) of the semiconductor die 130. The contact pad 132 forms a terminal 135 of the semiconductor die 130. The first surface 160_{S1} of the metallic body 160 that is exposed from the mold compound 110 redistributes the terminal 135 of semiconductor die 130 as a terminal 105 of the molded electronic component 100 through the plurality of metallic loops 150 that are attached to the second surface 160_{S2} of the metallic body 160. The metallic body 160 may be larger, e.g., have a larger surface area than the contact pad 132 as shown in FIG. 3. This may be advantageous in that the resulting molded electronic component has an increased contact surface facilitating connection and assembly. In examples where the semiconductor die 130 includes a transistor (e.g., a MOSFET, an IGBT), the terminal 135 formed by contact pad 132 may be a load terminal of the semiconductor die 130 such as source terminal, a drain terminal, an emitter terminal, or a collector terminal, or another terminal of a transistor, such as a gate terminal.

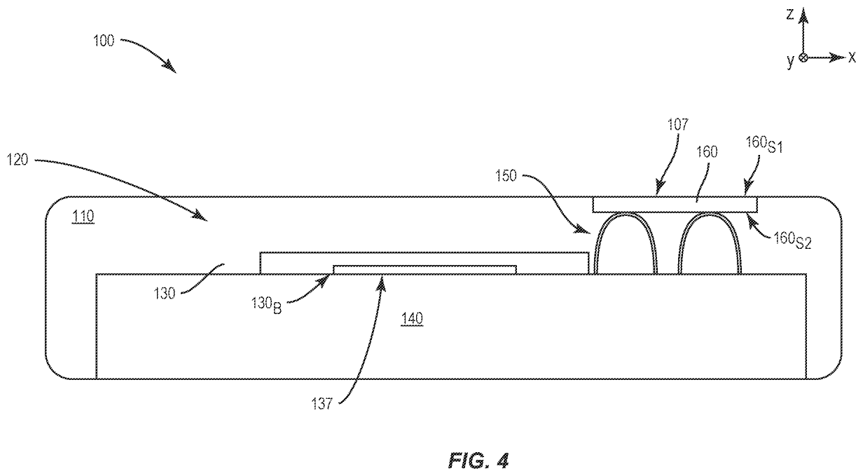

FIG. 4 illustrates a side cross-sectional view of the molded electronic component 100, according to an embodiment. FIG. 4 illustrates one example of the molded electronic component 100 of FIG. 1 and may include features of the other examples described herein.

Each of the plurality of metallic loops 150 of the molded electronic component 100 of FIG. 4 is attached to the die assembly 120 at a position on the substrate 140. A terminal 137 on a backside 130B of the semiconductor die 130 is attached to the substrate 140 such that the substrate 140 is at the same potential as the terminal 137. The terminal 137 may be electrically coupled to the plurality of metallic loops 150, e.g., through a trace, pad, or another layer of the substrate 140 that the plurality of metallic loops 150 is attached to. The first surface 160_{S1} of the metallic body 160 that is exposed from the mold compound 110 redistributes the terminal 137 as a terminal 107 of the molded electronic component 100 through the plurality of metallic loops 150 that are attached to the second surface 160_{S2} of the metallic body 160. In examples where the semiconductor die 130 includes a transistor (e.g., a MOSFET, an IGBT), the terminal 137 of the semiconductor die 130 may be a load terminal such as source terminal, a drain terminal, an emitter terminal, or a collector terminal, or another terminal of a transistor, such as a gate terminal.

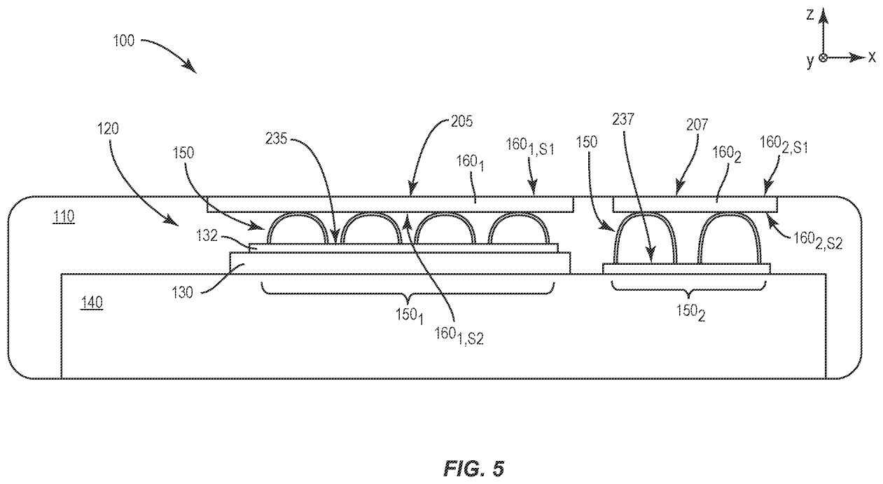

FIG. 5 illustrates a side cross-sectional view of the molded electronic component 100, according to an embodiment. FIG. 5 illustrates one example of the molded electronic component 100 of FIG. 1 and may include features of the other examples described herein.

The plurality of metallic loops 150 of the molded electronic component 100 of FIG. 5 includes a first plurality 150₁ of metallic loops 150 and a second plurality 150₂ of metallic loops 150. The first plurality 150₁ and the second plurality 150₂ of metallic loops 150 are each embedded in the mold compound 110 and attached to the die assembly 120.

Each of the first plurality 150₁ of metallic loops 150 is attached to the die assembly 120 at a first terminal 235 of the die assembly 120. Each of the second plurality 150₂ of metallic loops 150 is attached to the die assembly 120 at a second terminal 237 of the die assembly 120. In this example, the first terminal 235 of the die assembly 120 is a terminal of the semiconductor die 130. The first terminal 235 may, e.g., be a load terminal of the semiconductor die 130 that the contact pad 132 of the semiconductor die 130 forms. The second terminal 237 of the die assembly 120 is a terminal on the substrate 140. The second terminal 237 may be a load terminal, e.g., a redistributed load terminal of the semiconductor die 130 like the terminal 137 of FIG. 4. Other arrangements of the first terminal 235 and the second terminal 237 of the die assembly 120 are contemplated, e.g., an arrangement in which both the first terminal 235 and the second terminal 237 are terminals of the semiconductor die 130, and arrangement in which both the first terminal 235 and the second terminal 237 are terminals on the substrate 140.

The molded electronic component 100 of FIG. 5 includes a first metallic body 160₁ and a second metallic body 160₂ each partly embedded in the mold compound 110. Each of the first metallic body 160₁ and the second metallic body 160₂ may be a metallic body 160 of FIG. 1 or of any of the other examples described herein. The first metallic body 160₁ and the second metallic body 160₂ each has a first surface 160_{1,S1} and 160_{2,S1}, respectively, that is exposed from the mold compound 110. The first metallic body 160₁ is attached to each of the first plurality 150₁ of metallic loops 150 at a second surface 160_{1,S2} of the first metallic body 160₁ opposite the first surface 160_{1,S1} of the first metallic body 160₁. The second metallic body 160₂ is attached to each of the second plurality 150₂ of metallic loops 150 at a second surface 160_{2,S2} of the second metallic body 160₂ opposite the first surface 160_{2,S1} of the second metallic body 160₂.

The first surface 160_{1,S1} of the first metallic body 160₁ that is exposed from the mold compound 110 redistributes the first terminal 235 of the die assembly 120 as a first terminal 205 of the molded electronic component 100. The first surface 160_{2,S1} of the second metallic body 160₂ that is exposed from the mold compound 110 redistributes the second terminal 237 of the die assembly 120 as a second terminal 207 of the molded electronic component 100.

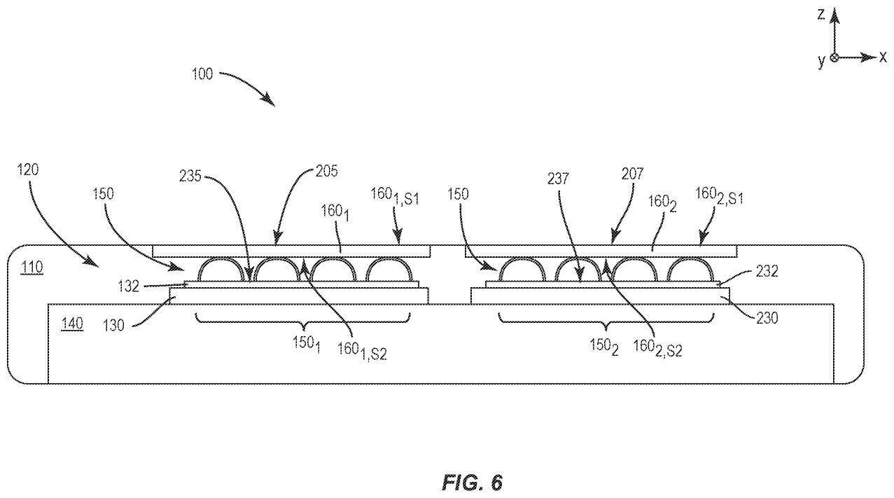

FIG. 6 illustrates a side cross-sectional view of the molded electronic component 100, according to an embodiment. FIG. 6 illustrates one example of the molded electronic component 100 of FIG. 1 and may include features of the other examples described herein.

In the example of FIG. 6, the die assembly 120 of the molded electronic component includes a second semiconductor die 230. The second semiconductor die 230 may include one or more devices, including transistors, diodes, resistors, capacitors, and/or other types of active or passive devices. Examples of transistors of the second semiconductor die 230 may include MOSFETs, IGBTs, and/or BJTs, among others. The second semiconductor die 230 and/or its constituent devices may be arranged to form all or part of a power electronics circuit such as a DC/AC inverter, a DC/DC converter, an AC/DC converter, a DC/AC converter, an AC/AC converter, a multi-phase inverter, an H-bridge, motor driver, etc. In some examples, a power electronics circuit that includes the second semiconductor die 230 is a half-bridge or full-bridge circuit. In some examples, the semiconductor die 130 and the second semiconductor die 230 form all or part of a power electronics circuit. In this example, the second semiconductor die 230 is attached to the same substrate that semiconductor die 130 is attached to, although examples in which the semiconductor die 130 and the second semiconductor die 230 are attached to different substrates are contemplated.

In this example, the second terminal 237 of the die assembly 120 that each of the second plurality 150₂ of metallic loops 150 is attached to is a terminal of the second semiconductor die 230. The second terminal 237 may, e.g., be a load terminal of the second semiconductor die 230 that is formed by a contact pad 232 of the second semiconductor die 230. The first surface 160_{2,S1} of the second metallic body 160₂ that is exposed from the mold compound 110 redistributes the second terminal 237 of the second semiconductor die 230 of the die assembly 120 as a second terminal 207 of the molded electronic component 100.

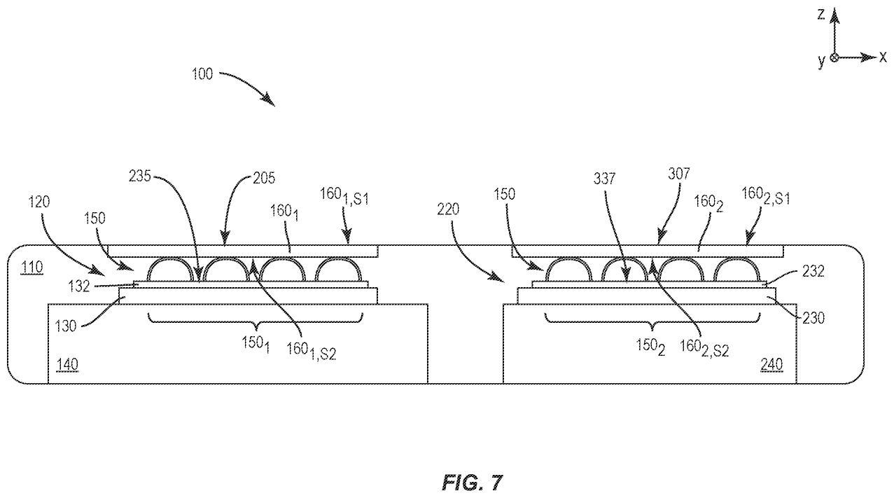

FIG. 7 illustrates a side cross-sectional view of the molded electronic component, according to an embodiment. FIG. 7 illustrates one example of the molded electronic component 100 of FIG. 1 and may include features of the other examples described herein.

The molded electronic component 100 of FIG. 7 includes a second die assembly 220 that includes the second semiconductor die 230 (e.g., the second semiconductor die 230 of FIG. 6) attached to a second substrate 240. The second substrate 240 may be a printed circuit board (PCB), lead frame, or other substrate, e.g., insulated metal substrate (IMS), a DCB (direct copper bonded) substrate, an AMB (active metal brazed), etc.

The second plurality 150₂ of metallic loops 150 is attached to the second die assembly 220 at a terminal 337 of the second die assembly 220. The first surface 160_{2,S1} of the second metallic body 160₂ that is exposed from the mold compound 110 redistributes the terminal 337 of the second die assembly 220 as a second terminal 307 of the molded electronic component 110. As in the example of the second terminal 237 of FIG. 6, the terminal 337 of FIG. 7 may be a load terminal of the second semiconductor die 230 that is formed by the contact pad 232. In other examples, the terminal 337 of the second die assembly 220 may be on the second substrate 240.

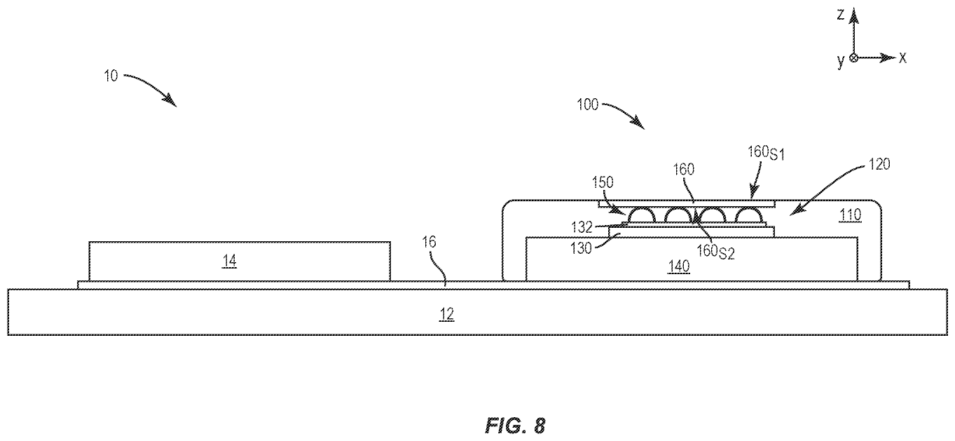

FIG. 8 illustrates a side cross-sectional view of a power electronics assembly 10, according to an embodiment. The power electronics assembly 10 includes a printed circuit board 12, the molded electronic component 100, and an electronic device 14 (e.g., a controller, another component such as a molded or frame-based electronic component, a gate driver, a chip, etc.). The molded electronic component 100 is embedded in the printed circuit board 12. The electronic device 14 is electrically connected to the molded electronic component 100 through the printed circuit board 12, e.g., through metallic trace(s) 16. The molded electronic component 100 illustrated in FIG. 8 is the molded electronic component 100 of FIG. 3 but may alternatively be the molded electronic component 100 of any of the examples described herein.

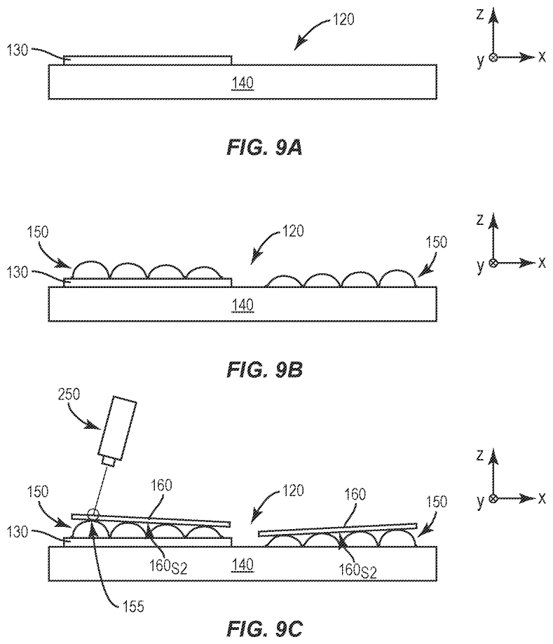

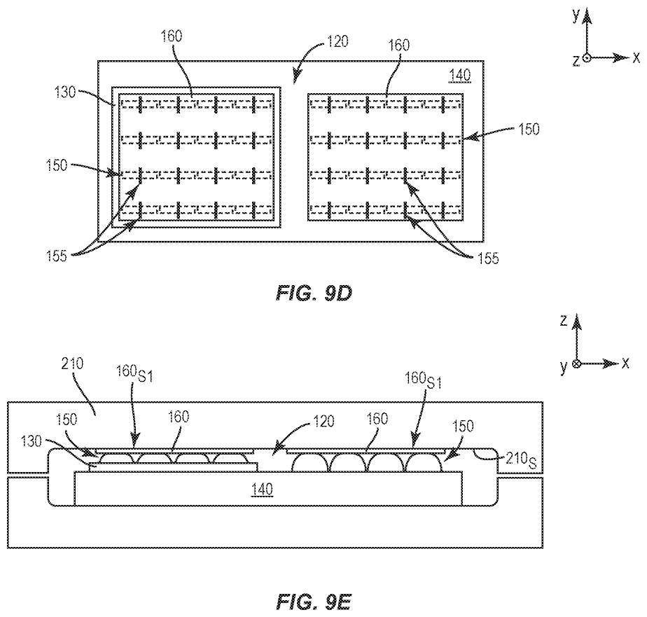

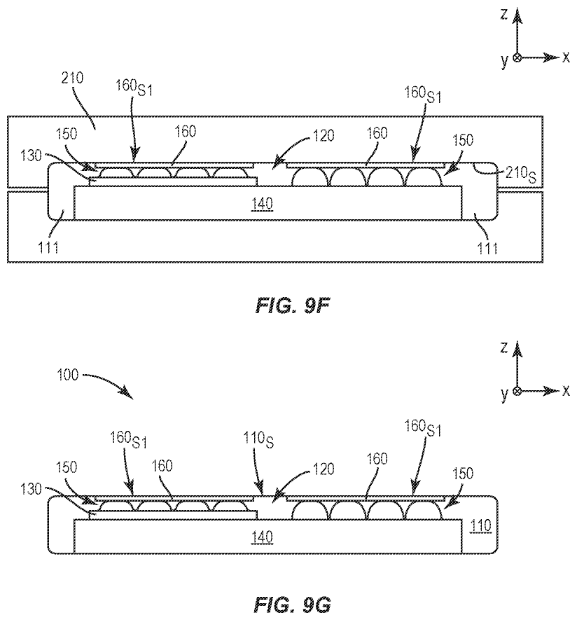

FIGS. 9A through 9G illustrate a method of producing the molded electronic component, according to an embodiment. The method of FIGS. 9A through 9G may be described with reference to the molded electronic component examples of FIGS. 1A-8.

FIG. 9A illustrates attaching the semiconductor die 130 to the substrate 140 to form the die assembly 120. FIG. 9B illustrates attaching the plurality of metallic loops 150 to the die assembly 120. The metallic loops 150 are illustrated with an exaggerated height variation in the z direction. FIG. 9C illustrates attaching the second surfaces 160_{S2} of the metallic bodies 160 to each of the plurality of metallic loops 150. FIG. 9C also illustrates vertical misalignment of the metallic bodies 160 in the z direction due to the height variation of the metallic loops 150. A vertical force (e.g., in the z direction) may be applied to the metallic bodies 160 at this juncture and/or at a later time to compress the metallic loops 150 and align the metallic bodies 160. FIG. 9C further illustrates a laser 250 used to attach the metallic bodies 160 to the metallic loops 150 with laser-welded joints 155. FIG. 9D illustrates a top view illustrating the laser-welded joints 155 perpendicular to the metallic loops 150. FIG. 9E illustrates enclosing the die assembly 120, the plurality of metallic loops 150, and the metallic bodies 160 in a mold 210. The mold 210 presses the metallic bodies 160 and the die assembly 120 towards one another, compressing the plurality of metallic loops 150 such that the metallic bodies 160 parallelly align against a surface 210_{S} of the mold 210 and with one another and eliminating gaps between the surfaces 160_{S1} of the metallic bodies 160 and the surface 210_{S} of the mold 210. The pressing force (e.g., in the z direction) applied by the mold 210 to the metallic bodies 160 compresses the metallic loops 150, reducing or even eliminating the height variation. FIG. 9F illustrates injecting a liquified mold compound 111 into the mold 210 while the metallic bodies 160 are aligned under the force of the surface 210_{S} of the mold 210. FIG. 9G illustrates the molded electronic component 100 after removal from the mold 210. The surfaces 160_{S1} of the metallic bodies 160 are flush with a surface 110_{S} of the mold compound 110. That is, the vertical misalignment of the metallic bodies that was present prior to forming the mold compound (e.g., in FIG. 9C) was reduced or eliminated during the formation of the mold compound (e.g., in FIGS. 9E and 9F).

Although the present disclosure is not so limited, the following numbered examples demonstrate one or more aspects of the disclosure.

Example 1: A molded electronic component, comprising: a mold compound; a die assembly comprising a semiconductor die attached to a substrate, the die assembly at least partly embedded in the mold compound; a plurality of metallic loops embedded in the mold compound and attached to the die assembly; and a metallic body partly embedded in the mold compound and having a first surface that is exposed from the mold compound, wherein the metallic body is attached to each of the plurality of metallic loops at a second surface of the metallic body opposite the first surface.

Example 2: The molded electronic component of example 1, wherein each of the plurality of metallic loops is attached to the die assembly at a position on a contact pad of the semiconductor die, wherein the contact pad forms a load terminal of the semiconductor die, and wherein the first surface of the metallic body that is exposed from the mold compound redistributes the load terminal of semiconductor die as a terminal of the molded electronic component.

Example 3: The molded electronic component of example 1, wherein each of the plurality of metallic loops is attached to the die assembly at a position on the substrate, wherein a load terminal on a backside of the semiconductor die is attached to the substrate such that the substrate is at the same potential as the load terminal, and wherein the first surface of the metallic body that is exposed from the mold compound redistributes the load terminal as a terminal of the molded electronic component.

Example 4: The molded electronic component of any of examples 1 through 3, wherein at least some of the plurality of metallic loops are shaped from bond wires that are attached to the die assembly at plurality of positions along a length of the bond wires.

Example 5: The molded electronic component of any of examples 1 through 4, wherein at least some of the plurality of metallic loops are shaped from discrete segments of bond wires, each segment comprising a first end and a second end that are attached to the die assembly at plurality of positions.

Example 6: The molded electronic component of any of examples 1 through 5, wherein at least some of the plurality of metallic loops are shaped from metallic ribbon that is attached to the die assembly at plurality of positions along a length of the metallic ribbon.

Example 7: The molded electronic component of any of examples 1 through 6, wherein the metallic body is attached to each of the plurality of metallic loops by one of a laser-welded joint, an adhesive, or a solder joint.

Example 8: The molded electronic component of any of examples 1 through 7, wherein the plurality of metallic loops is arranged in a plurality of rows of metallic loops on a surface of the die assembly.

Example 9: The molded electronic component of any of examples 1 through 8, wherein the plurality of metallic loops is a first plurality of metallic loops, and wherein the molded electronic component further comprises a second plurality of metallic loops embedded in the mold compound and attached to the die assembly.

Example 10: The molded electronic component of example 9, wherein the metallic body is attached to each of the second plurality of metallic loops at the second surface of the metallic body opposite the first surface.

Example 11: The molded electronic component of example 9, wherein the metallic body is a first metallic body, and wherein the molded electronic component further comprises a second metallic body partly embedded in the mold compound and having a first surface that is exposed from the mold compound, wherein the second metallic body is attached to each of the second plurality of metallic loops at a second surface of the second metallic body opposite the first surface of the second metallic body.

Example 12: The molded electronic component of example 11, wherein each of the first plurality of metallic loops is attached to the die assembly at a first load terminal of the die assembly, wherein the first surface of the first metallic body that is exposed from the mold compound redistributes the first load terminal of the die assembly as a first terminal of the molded electronic component, wherein each of the second plurality of metallic loops is attached to the die assembly at a second load terminal of the die assembly, and wherein the first surface of the second metallic body that is exposed from the mold compound redistributes the second load terminal of the die assembly as a second terminal of the molded electronic component.

Example 13: The molded electronic component of example 12, wherein the first load terminal of the die assembly is a load terminal of the semiconductor die.

Example 14: The molded electronic component of example 12 or 13, wherein the second load terminal of the die assembly is a load terminal on the substrate.

Example 15: The molded electronic component of example 12 or 13, wherein the semiconductor die is a first semiconductor die, wherein the die assembly further comprises a second semiconductor die attached to the same or a different substrate, and wherein the second load terminal is a load terminal of the second semiconductor die.

Example 16: The molded electronic component of any of examples 1 through 8, wherein the die assembly is a first die assembly, wherein the metallic body is a first metallic body, wherein the plurality of metallic loops is a first plurality of metallic loops, and wherein the molded electronic component further comprises: a second die assembly comprising a second semiconductor die attached to a second substrate; a second metallic body partly embedded in the mold compound and having a first surface that is exposed from the mold compound; and a second plurality of metallic loops embedded in the mold compound and attached to the second die assembly, wherein the second metallic body is attached to each of the second plurality of metallic loops at a second surface of the second metallic body opposite the first surface of the second metallic body.

Example 17: The molded electronic component of example 16, wherein each of the first plurality of metallic loops is attached to the first die assembly at a first load terminal of the first die assembly, wherein the first surface of the first metallic body that is exposed from the mold compound redistributes the first load terminal of the first die assembly as a first terminal of the molded electronic component, wherein each of the second plurality of metallic loops is attached to the second die assembly at a second load terminal of the second die assembly, and wherein the first surface of the second metallic body that is exposed from the mold compound redistributes the second load terminal of the second die assembly as a second terminal of the molded electronic component.

Example 18: A power electronics assembly comprising: a printed circuit board; a molded electronic component embedded in the printed circuit board and comprising: a mold compound; a die assembly comprising a semiconductor die attached to a substrate, the die assembly at least partly embedded in the mold compound; a plurality of metallic loops embedded in the mold compound and attached to the die assembly; and a metallic body partly embedded in the mold compound and having a first surface that is exposed from the mold compound, wherein the metallic body is attached to each of the plurality of metallic loops at a second surface of the metallic body opposite the first surface; and an electronic device electrically connected to the molded electronic component through the printed circuit board.

Example 19: A method of producing a molded electronic component, the method comprising: attaching a semiconductor die to a substrate to form a die assembly; attaching a plurality of metallic loops to the die assembly; attaching a first surface of a metallic body to each of the plurality of metallic loops; enclosing the die assembly, the plurality of metallic loops, and the metallic body in a mold such that the mold presses the metallic body and the die assembly towards one another and compresses the plurality of metallic loops; and injecting a liquified mold compound into the mold.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A molded electronic component, comprising:
a mold compound;
a die assembly comprising a semiconductor die attached to a substrate, the die assembly at least partly embedded in the mold compound;
a plurality of metallic loops embedded in the mold compound and attached to the die assembly; and
a metallic body partly embedded in the mold compound and having a first surface that is exposed from the mold compound,
wherein the metallic body is attached to each of the plurality of metallic loops at a second surface of the metallic body opposite the first surface.

2. The molded electronic component of claim 1,
wherein each of the plurality of metallic loops is attached to the die assembly at a position on a contact pad of the semiconductor die,
wherein the contact pad forms a load terminal of the semiconductor die, and
wherein the first surface of the metallic body that is exposed from the mold compound redistributes the load terminal of semiconductor die as a terminal of the molded electronic component.

3. The molded electronic component of claim 2,
wherein the metallic body has a surface area larger than that of the contact pad of the semiconductor die.

4. The molded electronic component of claim 1,
wherein each of the plurality of metallic loops is attached to the die assembly at a position on the substrate,
wherein a load terminal on a backside of the semiconductor die is attached to the substrate such that the substrate is at the same potential as the load terminal, and
wherein the first surface of the metallic body that is exposed from the mold compound redistributes the load terminal as a terminal of the molded electronic component.

5. The molded electronic component of claim 1, wherein at least some of the plurality of metallic loops are shaped from bond wires that are attached to the die assembly at plurality of positions along a length of the bond wires.

6. The molded electronic component of claim 1, wherein at least some of the plurality of metallic loops are shaped from discrete segments of bond wires, each segment comprising a first end and a second end that are attached to the die assembly at plurality of positions.

7. The molded electronic component of claim 1, wherein at least some of the plurality of metallic loops are shaped from metallic ribbon that is attached to the die assembly at plurality of positions along a length of the metallic ribbon.

8. The molded electronic component of claim 1, wherein at least some of the plurality of loops are resilient.

9. The molded electronic component of claim 1, wherein the metallic body is attached to each of the plurality of metallic loops by one of a laser-welded joint, an adhesive, or a solder joint.

10. The molded electronic component of claim 1, wherein the plurality of metallic loops is arranged in a plurality of rows of metallic loops on a surface of the die assembly.

11. The molded electronic component of claim 1,
wherein the plurality of metallic loops is a first plurality of metallic loops, and
wherein the molded electronic component further comprises a second plurality of metallic loops embedded in the mold compound and attached to the die assembly.

12. The molded electronic component of claim 11, wherein the metallic body is attached to each of the second plurality of metallic loops at the second surface of the metallic body opposite the first surface.

13. The molded electronic component of claim 11,
wherein the metallic body is a first metallic body, and
wherein the molded electronic component further comprises a second metallic body partly embedded in the mold compound and having a first surface that is exposed from the mold compound,
wherein the second metallic body is attached to each of the second plurality of metallic loops at a second surface of the second metallic body opposite the first surface of the second metallic body.

14. The molded electronic component of claim 13,
wherein each of the first plurality of metallic loops is attached to the die assembly at a first load terminal of the die assembly,
wherein the first surface of the first metallic body that is exposed from the mold compound redistributes the first load terminal of the die assembly as a first terminal of the molded electronic component,
wherein each of the second plurality of metallic loops is attached to the die assembly at a second load terminal of the die assembly, and
wherein the first surface of the second metallic body that is exposed from the mold compound redistributes the second load terminal of the die assembly as a second terminal of the molded electronic component.

15. The molded electronic component of claim 14, wherein the first load terminal of the die assembly is a load terminal of the semiconductor die.

16. The molded electronic component of claim 14, wherein the second load terminal of the die assembly is a load terminal on the substrate.

17. The molded electronic component of claim 14,
wherein the semiconductor die is a first semiconductor die,
wherein the die assembly further comprises a second semiconductor die attached to the same or a different substrate, and
wherein the second load terminal is a load terminal of the second semiconductor die.

18. The molded electronic component of claim 1,
wherein the die assembly is a first die assembly,
wherein the metallic body is a first metallic body,
wherein the plurality of metallic loops is a first plurality of metallic loops, and
wherein the molded electronic component further comprises:
a second die assembly comprising a second semiconductor die attached to a second substrate;
a second metallic body partly embedded in the mold compound and having a first surface that is exposed from the mold compound; and
a second plurality of metallic loops embedded in the mold compound and attached to the second die assembly,
wherein the second metallic body is attached to each of the second plurality of metallic loops at a second surface of the second metallic body opposite the first surface of the second metallic body.

19. The molded electronic component of claim 18,
wherein each of the first plurality of metallic loops is attached to the first die assembly at a first load terminal of the first die assembly,
wherein the first surface of the first metallic body that is exposed from the mold compound redistributes the first load terminal of the first die assembly as a first terminal of the molded electronic component,
wherein each of the second plurality of metallic loops is attached to the second die assembly at a second load terminal of the second die assembly, and
wherein the first surface of the second metallic body that is exposed from the mold compound redistributes the second load terminal of the second die assembly as a second terminal of the molded electronic component.

20. A power electronics assembly comprising:
a printed circuit board;
a molded electronic component embedded in the printed circuit board and comprising:
a mold compound;
a die assembly comprising a semiconductor die attached to a substrate, the die assembly at least partly embedded in the mold compound;
a plurality of metallic loops embedded in the mold compound and attached to the die assembly; and
a metallic body partly embedded in the mold compound and having a first surface that is exposed from the mold compound,
wherein the metallic body is attached to each of the plurality of metallic loops at a second surface of the metallic body opposite the first surface; and
an electronic device electrically connected to the molded electronic component through the printed circuit board.

21. A method of producing a molded electronic component, the method comprising:
attaching a semiconductor die to a substrate to form a die assembly;
attaching a plurality of metallic loops to the die assembly;
attaching a first surface of a metallic body to each of the plurality of metallic loops;
enclosing the die assembly, the plurality of metallic loops, and the metallic body in a mold such that the mold presses the metallic body and the die assembly towards one another and compresses the plurality of metallic loops; and
injecting a liquified mold compound into the mold.
